(19) United States
(12) Patent Application Publication
(10) Pub. No.: US 2025/0071932 A1
(43) Pub. Date: Feb. 27, 2025

(54) MOTION BODY AND COUPLING METHOD THEREOF

(71) Applicant: FIVEGRAND INTERNATIONAL CO., LTD., New Taipei City (TW)

(72) Inventor: TING-JUI WANG, New Taipei City (TW)

(73) Assignee: FIVEGRAND INTERNATIONAL CO., LTD., New Taipei City (TW)

(21) Appl. No.: 18/805,557

(22) Filed: Aug. 15, 2024

(30) Foreign Application Priority Data
Aug. 21, 2023 (TW) 112131320

(51) Int. Cl. H05K 7/18; H05K 7/10

(52) U.S. Cl. CPC H05K 7/183; H05K 7/1007

(57) ABSTRACT

A motion body and a coupling method thereof are introduced. The motion body includes a first body and a coupling portion. The coupling portion is provided with a second body and an elastic element. The second body is disposed at the first body, and two ends of the elastic element respectively abut against the coupling portion and the second body to allow the coupling portion to enter a counterpart object and be located at a residing position or a pause position, enabling the motion body to be elastically assembled or elastically fastened with the counterpart object and to lift or fix an object by the first body. Thus, with coordination of the motion body, the counterpart object and the object, quick coupling of at least two objects can be completed to achieve effects of repeatedly quick coupling and separation.

### CROSS-REFERENCE TO RELATED APPLICATION

This non-provisional application claims priority under 35 U.S.C. § 119 (a) on Patent Application No(s). 112131320 filed in Taiwan, R.O.C. on Aug. 21, 2023, the entire contents of which are hereby incorporated by reference.

### BACKGROUND OF THE INVENTION

### 1. Field of the Invention

The present disclosure relates to a motion body and a coupling method thereof, and in particular to a motion body operable for repeatedly and quickly coupling and separating at least two objects and a coupling method thereof.

### 2. Description of the Related Art

In general, when at least one object is to be coupled, lock connection is usually performed using a screw for coupling the object.

In the conventional fixing means above, although at least one object can be fixed and coupled in a form that is not easily separated, in addition to unhandy assembly, the at least one object may not be easily removed due to the fixed coupling means using the screw.

### BRIEF SUMMARY OF THE INVENTION

In view of the prior art above, the applicant develops a motion body and a coupling method thereof by which complete quick coupling of at least two objects in the aim of achieving effects of repeated and quickly coupling and separation.

To achieve the above and other objects, the present disclosure provides a motion body including a first body and a coupling portion. The coupling portion is provided with a second body and an elastic element. The second body is disposed at the first body, and two ends of the elastic element respectively abut against the coupling portion and the second body to enable the motion body to be elastically assembled or elastically fastened with a counterpart object.

The present disclosure further provides a motion body including a first body and a coupling portion. The coupling portion is disposed at the first body for the coupling portion to be assembled or fastened with a counterpart object, wherein the first body is provided with at least one stop portion for stopping or limiting an object.

The present disclosure further provides a motion body including a first body and a coupling portion. The coupling portion is disposed at the first body for the coupling portion to be assembled or fastened with a counterpart object, wherein the first body is provided with an elastic bending portion. The elastic bending portion elastically faces a direction opposite to the coupling portion or elastically faces a direction of the coupling portion, and is for the motion body to be fastened to an object.

The present disclosure further provides a motion body including a first body and a coupling portion. The coupling portion is disposed at the first body for the coupling portion to be assembled or fastened with a counterpart object, wherein the first body is elastic, has an abutting portion and is for the motion body to be fastened to an object.

In the motion body above, the first body is provided with a handle. The handle and the first body are formed integrally, or the handle and the first body are movably assembled, or the handle and the counterpart object are fastened, assembled, labor-saving pushed, pushed or leverage pushed to move the motion body.

In the motion body above, the counterpart object is provided with a movement space, and the coupling portion moves in the movement space.

In the motion body above, the movement space is provided with an entrance and a passage, and the coupling portion enters the entrance and moves in the passage.

In the motion body above, the movement space is provided with at least one block portion. The block portion blocks the coupling portion at a residing position, a pause position or a restricted region.

In the motion body above, the block portion is provided with an entrance on a top or at a bottom, or two block portions are provided with an entrance on a top, in a middle or at a bottom, respectively, wherein the entrance is for the coupling portion to enter.

In the motion body above, the coupling portion enters the entrance on the top.

In the motion body above, the coupling portion enters the entrance in the middle.

In the motion body above, the coupling portion enters the entrance at the bottom.

In the motion body above, the block portion is a protrusion, a recess, a step or a protrusion having a central channel.

In the motion body above, the coupling portion blocks, passes through, fittingly engages with or elastically presses against the block portion by elastic expansion/retraction of the elastic element.

In the motion body above, the second body and the first body are riveted, expansion connected, insert connected, fastened, welded or locked, or the second body and the first body are formed integrally.

The motion body above is provided with a lift portion, which is provided at the first body and is for lifting an object.

In the motion body above, the motion body or an object resides, pauses or restricts a region at the coupling portion or a blocking position of at least one block portion along with the first body.

In the motion body above, the counterpart object or the object is a server, a storage device, a memory, an integrated circuit (IC), an M2 memory, an EI.S memory, an E3.S memory, a computer, a cabinet, a motherboard, a circuit board, a heat sink, a chip, a metal body, a non-metal body or a hard drive.

In the motion body above, the counterpart object is provided with a movement space having an entrance or at least one limiting portion. The coupling portion enters the entrance, and is elastically fastened, elastically pressed, limited or temporarily limited at the limiting portion.

In the motion body above, the coupling portion is provided with a restricting portion, enters the entrance, and is elastically fastened, elastically pressed, limited or temporarily limited at the limiting portion by the restricting portion.

In the motion body above, the limiting portion is two in quantity, the coupling portion is elastically fastened, elastically pressed, limited or temporarily limited at each of the limiting portions in a two-stage or multi-stage manner.

In the motion body above, wherein an object is lifted by one motion body or two motion bodies, and the object is a server, a storage device, a memory, an integrated circuit (IC), an M2 memory, an EI.S memory, an E3.S memory, a computer, a cabinet, a motherboard, a circuit board, a heat sink, a chip, a metal body, a non-metal body or a hard drive.

In the motion body above, the object is provided with a connector, the counterpart object is provided with a corresponding connector, and the motion body is for docking, plugging or hot-plugging with the corresponding connector by the connector.

In the motion body above, the first body is provided with a labor-saving push portion, and the labor-saving push portion and the counterpart object are labor-saving pushed or leverage pushed to move the motion body.

In the motion body above, wherein an object is provided with at least one positioning portion which is positioned or limited with the motion body.

In the motion body above, the first body is provided with at least one stop portion for stopping or limiting an object.

In the motion body above, the stop portion is provided with a rail, and the object moves along a direction of the rail.

In the motion body above, the first body is provided with at least one fixing portion, and an object is fixed at the first body by the fixing portion.

In the motion body above, the elastic bending portion is pushed by the object and the counterpart object so as to bend back, reduce a curvature, guide an angle, return to alignment or approach alignment.

In the motion body above, the elastic bending portion is pushed by the counterpart object so as to bend back, reduce a curvature, guide an angle, return to alignment or approach alignment.

In the motion body above, the abutting portion abuts against the counterpart object, and the coupling portion is for coupling the counterpart object for the first body with elasticity to bend and be fastened or assembled with the counterpart object.

In the motion body above, the abutting portion abuts against the counterpart object, and the coupling portion is for coupling the counterpart object for a handle of the first body with elasticity to bend and be fastened or assembled with the counterpart object.

In the motion body above, the first body is elastic or is a metal or plastic substance provided with elasticity after a thermal treatment.

The present disclosure further provides a coupling method for a motion body. The coupling portion enters the entrance on the top, and the coupling portion is retained at a residing position, a pause position or a restricted region by the block portion or the block portions; or the coupling portion enters the entrance on the top, and the motion body is retained at a residing position, a pause position or a restricted region by the block portion or the block portions; or the coupling portion enters the entrance in the middle, and the coupling portion is retained at a residing position, a pause position or a restricted region by the block portion or the block portions; or the coupling portion enters the entrance in the middle, and the motion body is retained at a residing position, a pause position or a restricted region by the block portion or the block portions; or the coupling portion enters the entrance at the bottom, and the coupling portion is retained at a residing position, a pause position or a restricted region by the block portion or the block portions; or the coupling portion enters the entrance at the bottom, and the motion body is retained at a residing position, a pause position or a restricted region by the block portion or the block portions.

Thus, the motion body and the coupling method of the present disclosure, with coordination of the motion body, the counterpart object and the object, are capable of completing quick coupling of at least two objects so as to achieve effects of repeatedly quick coupling and separation.

### BRIEF DESCRIPTION OF THE DRAWINGS

FIG. 1 is a schematic diagram of a state of use according to a first embodiment of the present disclosure.

FIG. 2 is a schematic diagram according to a second embodiment of the present disclosure.

FIG. 3 is a schematic diagram according to a third embodiment of the present disclosure.

FIG. 4 is a schematic diagram according to a fourth embodiment of the present disclosure.

FIG. 5 is a schematic diagram according to a fifth embodiment of the present disclosure.

FIG. 6 is a schematic diagram of a state of use according to a sixth embodiment of the present disclosure.

FIG. 7 is a schematic diagram of a state of use according to a seventh embodiment of the present disclosure.

FIG. 8 is a schematic diagram of a state of use according to an eighth embodiment of the present disclosure.

FIG. 9 is a schematic diagram of a state of use according to a ninth embodiment of the present disclosure.

FIG. 10 is a schematic diagram according to a tenth embodiment of the present disclosure.

FIG. 11 is a schematic diagram of a state of use according to an eleventh embodiment of the present disclosure.

FIG. 12A is an appearance schematic diagram according to a twelfth embodiment of the present disclosure.

FIG. 12B is an appearance schematic diagram according to a thirteenth embodiment of the present disclosure.

FIG. 13 is a schematic diagram according to the twelfth embodiment of the present disclosure.

FIG. 14 is a schematic diagram of a state of use according to a fourteenth embodiment of the present disclosure.

FIG. 15 is a schematic diagram of a state of use according to the twelfth embodiment of the present disclosure.

FIG. 16 is a schematic diagram of a state of use according to a fifteenth embodiment of the present disclosure.

FIG. 17 is a schematic diagram of a state of use according to a sixteenth embodiment of the present disclosure.

FIG. 18 is a schematic diagram of a state of use according to a seventeenth embodiment of the present disclosure.

FIG. 19 is a schematic diagram of a state of use according to an eighteenth embodiment of the present disclosure.

FIG. 20 is a schematic diagram of a state of use according to the eighteenth embodiment of the present disclosure.

### DETAILED DESCRIPTION OF THE INVENTION

To facilitate understanding of the object, characteristics and effects of the present disclosure, embodiments together with the attached drawings for the detailed description of the present disclosure are provided below.

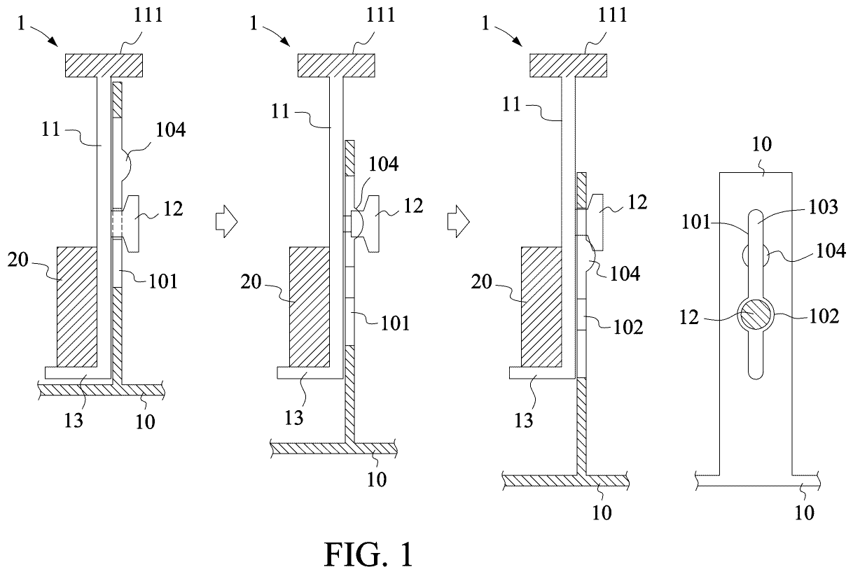

Referring to FIG. 1 to FIG. 3, as shown in the drawings, the present disclosure provides a motion body 1 and a coupling method thereof. The motion body 1 includes a first body 11 and a coupling portion 12.

The coupling portion 12 is provided with a second body 121 and an elastic element 122. The second body 121 is disposed at the first body 11. Two ends of the elastic element 122 respectively abut against the coupling portion 12 and the second body 121 to enable the motion body 1 to be elastically assembled or elastically fastened with a counterpart object 10.

When in use, the coupling portion 12 can be disposed at the counterpart object 10 by means of elastic assembling or elastic fastening, an object 20 is disposed at the first body 11, and the first body 11 is pulled during an operation. Then, the coupling portion 12 can be unfastened from the counterpart object 10, and the first body 11 is pulled to separate the object 20 from the counterpart object 10. Thus, quick coupling and separation of at least two objects (the counterpart object 10 and the object 20) can be completed to achieve effects of repeatedly quick coupling and separation.

In addition to the embodiments above, in one embodiment of the present disclosure, the first body 11 is provided with a handle 111. The handle 111 and the first body 11 are formed integrally, or the handle 111 and the first body 11 are movably assembled, or the handle 111 and the counterpart object 10 are fastened, assembled, labor-saving pushed, pushed or leverage pushed to move the motion body 1. Thus, a force can be applied to the handle 111 to move the first body 11, so as to achieve an effect of operating the first body 11 with ease.

In addition to the embodiments above, in one embodiment of the present disclosure, the counterpart object 10 is provided with a movement space 101, and the coupling portion 12 moves in the movement space 101. The movement space 101 is provided with an entrance 102 and a passage 103. The entrance 102 is for the coupling portion 12 to enter, so that the coupling portion 12 enters the entrance 102 and moves in the passage 103. The movement space 101 is provided with at least one block portion 104. The block portion 104 blocks the coupling portion 12 at a residing position, a pause position or a restricted region. The block portion 104 is provided with the entrance 102 on a top or at a bottom, and the entrance 102 is disposed at the bottom of the block portion 104 in an embodiment of the present disclosure.

On the basis of the embodiments above, the coupling portion 12 enters the entrance 102 at the bottom to allow the coupling portion 12 to block, pass through, fittingly engage with or elastically press against the block portion 104 by elastic expansion/retraction of the elastic element 122, and the coupling portion 12 (or the motion body 1) is retained at a residing position, a pause position or a restricted region by the block portion 104, thereby elastically assembling, elastically fastening or separating the coupling portion 12 and the counterpart object 10 with/from each other.

Moreover, the coupling portion 12 can also enter the entrance 102 on the top, and the coupling portion 12 (or the motion body 1) is retained at a residing position, a pause position or a restricted region by the block portion 104, similarly elastically assembling, elastically fastening or separating the coupling portion 12 and the counterpart object 10 with/from each other.

In addition to the embodiments above, in one embodiment of the present disclosure, the block portion 104 can be a protrusion, a recess, a step or a protrusion having a central channel, thereby enabling the block portion 104 to better meet actual application requirements.

In addition to the embodiments above, in one embodiment of the present disclosure, the motion body 1 is provided with a lift portion 13. The lift portion 13 is disposed at the first body 11, and is for lifting the object 20. When the first body 11 is pulled to drive the lift portion 13, the object 20 (or the motion body 1) can reside, pause or restrict a region at the coupling portion 12 or a blocking position of the block portion 104 along with the lift portion 13 (or the first body 11). Thus, the first body 11 can coordinate with the lift portion 13 to dispose or lift the object 20, thereby enabling the present disclosure to better meet actual application requirements.

In addition to the embodiments above, in one embodiment of the present disclosure, the counterpart object 10 or the object 20 can be a server, a storage device, a memory, an integrated circuit (IC), an M2 memory, an EI.S memory, an E3.S memory, a computer, a cabinet, a motherboard, a circuit board, a heat sink, a chip, a metal body, a non-metal body or a hard drive, thereby enabling the counterpart object 10 and the object 20 to better meet actual application requirements.

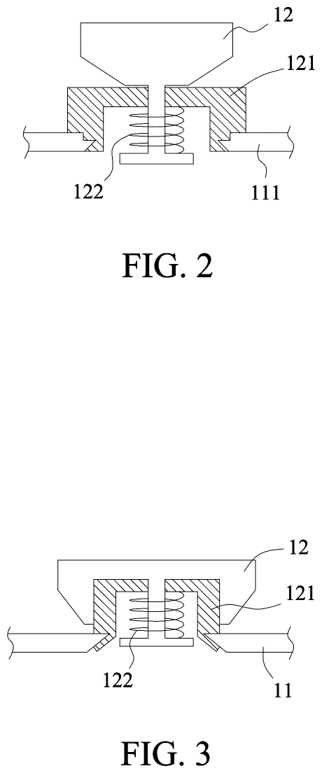

In addition to the embodiments above, in one embodiment of the present disclosure, the second body 121 of the coupling portion 12 and the first body 11 are riveted (as shown in FIG. 2), expansion connected (as shown in FIG. 3), insert connected, fastened, welded or locked, or the second body 121 and the first body 11 are formed integrally. Thus, the coupling portion 12 and the first body 11 can achieve a stable coupling effect.

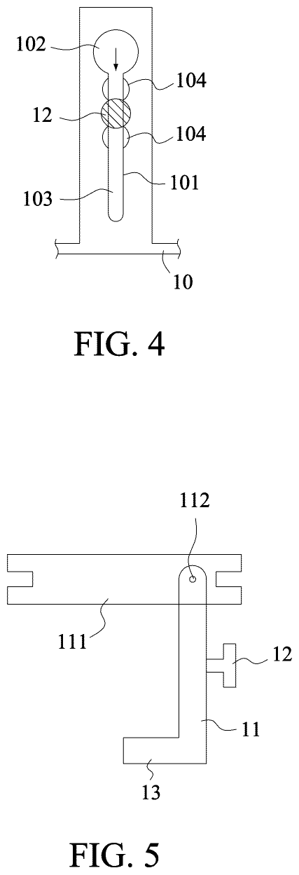

Referring to FIG. 4, as shown in the drawing, in addition to the embodiments above, in one embodiment of the present disclosure, the block portion 104 is two in quantity, and the entrance 102 is provided individually on the top, in the middle or at the bottom of the two block portions 104. In this embodiment, the entrance 102 is disposed on the top of the block portions 104.

On the basis of the embodiments above, the coupling portion 12 can enter the entrance 102 on the top, and the coupling portion 12 (or the motion body 1) is retained at a residing position, a pause position or a restricted region by the block portions 104, respectively, thereby elastically assembling, elastically fastening or separating the coupling portion 12 and the counterpart object 10 with/from each other.

Moreover, the coupling portion 12 can also enter the entrance 102 in the middle, and the coupling portion 12 (or the motion body 1) is retained at a residing position, a pause position or a restricted region by the block portions 104, similarly elastically assembling, elastically fastening or separating the coupling portion 12 and the counterpart object 10 with/from each other.

Referring to FIG. 5, as shown in the drawing, in addition to the embodiments above, in one embodiment of the present disclosure, the first body 11 and the handle 111 are movably assembled by a bolt 112. Thus, the handle 111 can be turned by the bolt 112 for the handle 111 to drive the first body 11 and the lift portion 13 by an appropriate angle, such that the object 20 is lifted by the lift portion 13, thereby completing quick coupling and separation of at least two objects and achieving an effect of repeatedly quick coupling and separation.

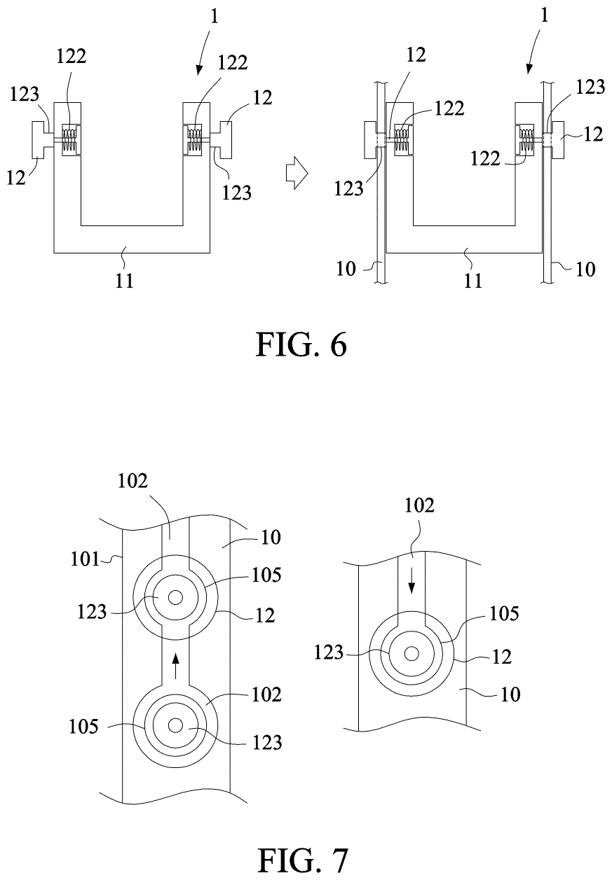

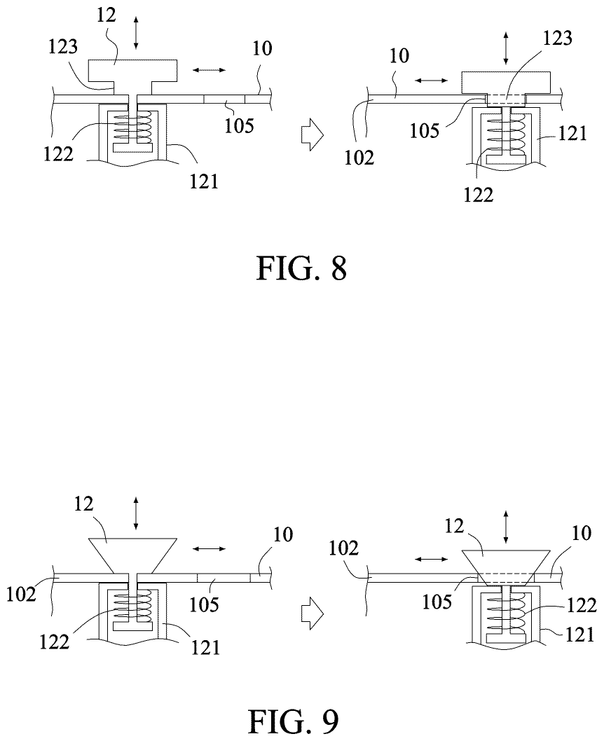

Referring to FIG. 6 to FIG. 10, as shown in the drawings, in addition to the embodiments above, in one embodiment of the present disclosure, the first body 11 can be in the form of a handle, the coupling portion 12 is two in quantity and the two coupling portions 12 are respectively disposed on two sides of the first body 11 (the coupling portions 12 can correspond in position to each other or be arranged in a staggered manner), and the movement space 101 is provided on each of two sides of the counterpart object 10. Each of the movement spaces 101 is provided with an entrance 102 and at least one limiting portion 105, the coupling portions 12 respectively enter the entrances 102, and the coupling portions 12 can be elastically fastened, elastically pressed, limited or temporarily limited at the limiting portions 105, thereby completing assembling and separation of the motion bodies 1 and the counterpart object 10.

In addition to the embodiments above, in one embodiment of the present disclosure, each of the coupling portions 12 is provided with a restricting portion 123, and the coupling portions 12 can enter the entrances 102 and be elastically fastened, elastically pressed, limited or temporarily limited at the limiting portions 105 by the restricting portions 123.

Moreover, the coupling portions 12 can also exclude the restricting portion 123 (as shown in FIG. 9) according to actual application requirements, and assembling and separation of the motion bodies 1 and the counterpart object 10 can similarly be completed.

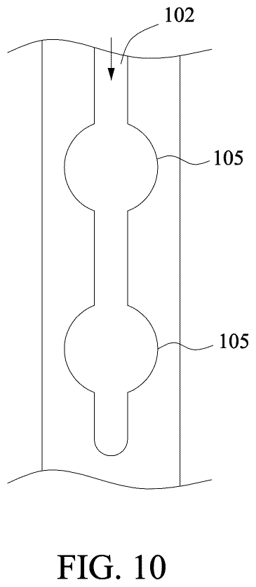

In addition to the embodiments above, in one embodiment of the present disclosure, the limiting portion 105 is two in quantity (as shown in FIG. 10), and the coupling portions 12 are elastically fastened, elastically pressed, limited or temporarily limited respectively at the limiting portions 105 in a two-stage or multi-stage manner, thereby enabling the present disclosure to better meet actual application requirements.

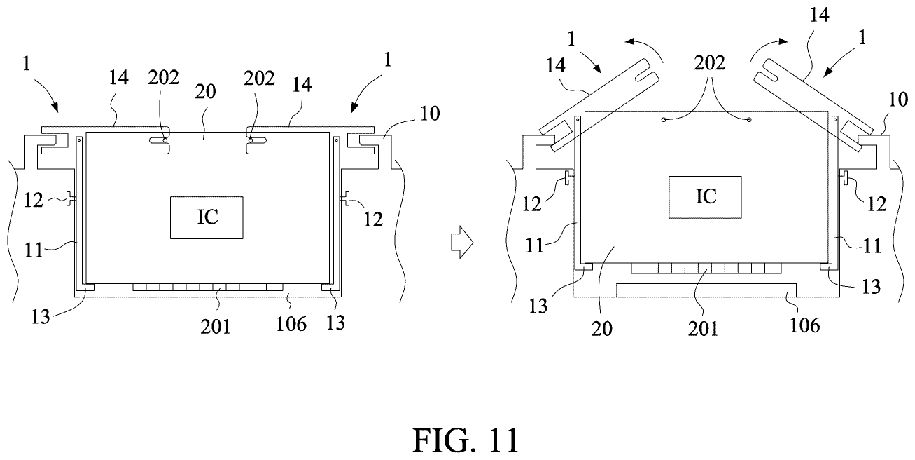

Referring to FIG. 11, as shown in the drawing, in addition to the embodiments above, in one embodiment of the present disclosure, the motion body 1 is two in quantity, the object 20 is simultaneously lifted by the two motion bodies 1, and the object 20 can be a server, a storage device, a memory, an integrated circuit (IC), an M2 memory, an EI.S memory, an E3.S memory, a computer, a cabinet, a motherboard, a circuit board, a heat sink, a chip, a metal body, a non-metal body or a hard drive.

In addition to the embodiments above, in one embodiment of the present disclosure, the object 20 is provided with a connector 201, the connector 201 is for connecting with a corresponding connector 106 of the counterpart object 10, and the motion bodies 1 are for docking, plugging or hot-plugging with the corresponding connector 106 by the connector 201.

In addition to the embodiments above, in one embodiment of the present disclosure, each of the first bodies 11 of the motion bodies 1 is provided with a labor-saving push portion 14, and the labor-saving push portions 14 and the counterpart object 10 are labor-saving pushed or leverage pushed to move the motion bodies 1.

In addition to the embodiments above, in one embodiment of the present disclosure, the object 20 is provided with at least one positioning portion 202, two positioning portions 202 are used in an embodiment of the present disclosure, and the positioning positions 202 are respectively positioned or limited with the motion bodies 1.

On the basis of the embodiments above, when in use, the labor-saving push portions 14 are respectively fastened to the positioning portions 202, and are fastened to the counterpart object 10 by the coupling portions 12, respectively. When the labor-saving push portions 14 of the motion bodies 1 separate from the positioning portions 202 of the object 20, the labor-saving push portions 14 and the counterpart object 10 push each other to move the motion bodies 1, for the motion bodies 1 to drive the first bodies 11 and the lift portions 13 by an appropriately angle, further lifting the object 20 to move upward by the lifting portions 13 and at the same time separating the connector 201 from the counterpart connector 106. Thus, the motion bodies 1 and the labor-saving push portions 14 are allowed to fasten or unfasten the counterpart object 10 and the object 20, so as to complete quick coupling and separation of at least two objects, thereby achieving an effect of repeatedly quick coupling and separation.

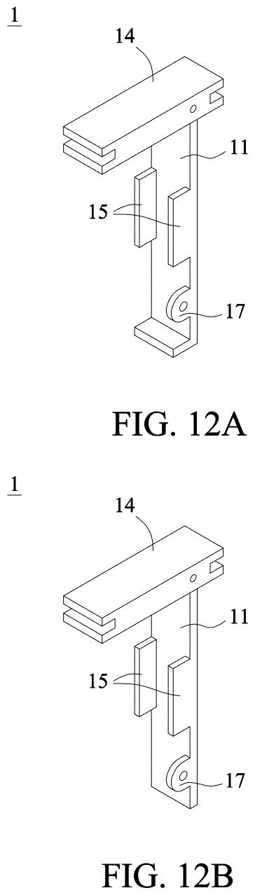

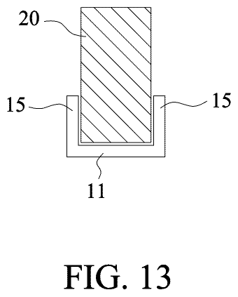

Referring to FIG. 12A to FIG. 15, as shown in the drawings, in addition to the embodiments above, in one embodiment of the present disclosure, the coupling portion 12 of the motion body 1 is disposed at the first body 11 for the coupling portion 12 to be assembled or fastened with the counterpart object 10. The first body 11 is provided with at least one stop portion 15, with two stop portions 15 used in an embodiment of the present disclosure, as shown in FIG. 12A and FIG. 12B, and the stop portions 15 are for stopping or limiting the object 20 (as shown in FIG. 13). Thus, the first body 11 of the present disclosure can coordinate with the stop portions 15 to better meet actual application requirements.

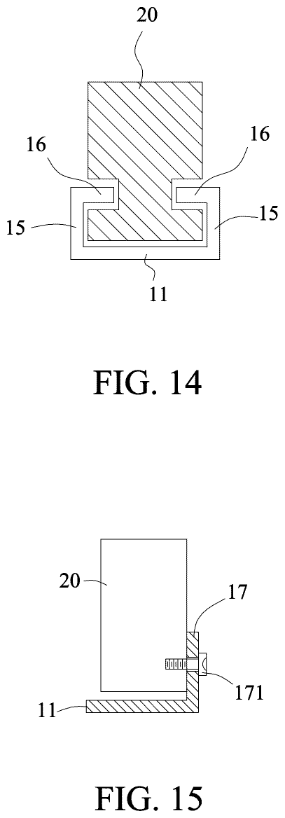

In addition to the embodiments above, in one embodiment of the present disclosure, each of the stop portions 15 is provided with a rail 16, for the object 20 to move along a direction of the rails 16 (as shown in FIG. 14). Thus, the first body 11 of the present disclosure can coordinate with the stop portions 15 and the rails 16 to better meet actual application requirements.

In addition to the embodiments above, in one embodiment of the present disclosure, the first body 11 is provided with at least one fixing portion 17, and the object 20 is fixed at the first body 11 by the fixing portion 17 coordinating with a fixing element 171 (as shown in FIG. 15). Thus, the first body 11 of the present disclosure can coordinate with the fixing portion 17 and the fixing element 171 to better meet actual application requirements.

In addition to the embodiments above, in one embodiment of the present disclosure, the motion body 1 (or the object20) resides, pauses or restricts a region at the coupling portion 12 or a blocking position of the block portion 104 along with the first body 11. Thus, the first body 11 can better meet actual application requirements.

Moreover, the motion body 1 can be provided with the lift portion 13 (as shown in FIG. 12A), or be not provided with the lift portion 13 (as shown in FIG. 12B) according to actual application requirements. Thus, the motion body 1 of the present disclosure can better meet actual application requirements.

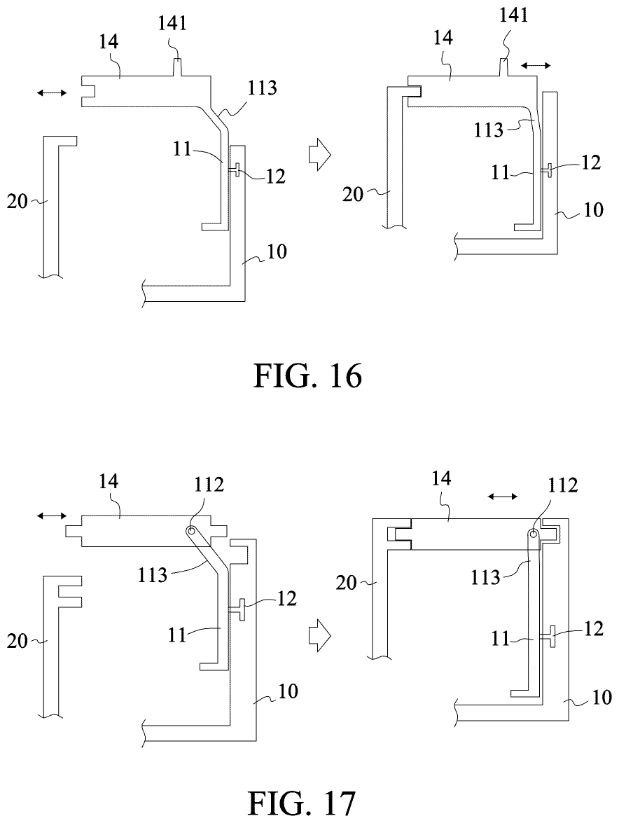

Referring to FIG. 16 to FIG. 18, as shown in the drawings, in addition to the embodiments above, in one embodiment of the present disclosure, the first body 11 has an elastic bending portion 113 (a bent portion or an elastic portion). The elastic bending portion 113 elastically faces a direction opposite to the coupling portion 12 to provide the motion body 1 with elasticity when the motion body 1 is elastically fastened to the object 20.

When in use for fastening, the coupling portion 12 can be fastened to the counterpart object 10, and is fastened to the object 20 by the labor-saving push portion 14, so as to provide the motion body 1 with elasticity when the motion body 1 is elastically fastened to the object 20 by using the elastic bending portion 113. For unfastening, a force can be applied to an operating portion 141 of the labor-saving push portion 14, and the labor-saving push portion 14 is unfastened from the object 20 by using the coordination of the elastic bending portion 113. Thus, quick coupling and separation of at least two objects (the counterpart object 10 and the object 20) can be completed to achieve effects of repeatedly quick coupling and separation.

In addition to the embodiments above, in one embodiment of the present disclosure, the elastic bending portion 113, the first body 11 and the labor-saving push portion 14 are formed integrally (as shown in FIG. 16), or the elastic bending portion 113 is movably assembled with the labor-saving push portion 14 by the bolt 112 (as shown in FIG. 17). Thus, the motion body 1 of the present disclosure can better meet actual application requirements.

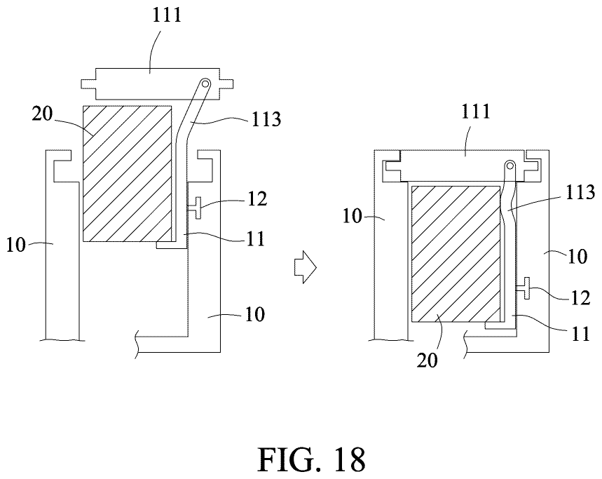

In addition to the embodiments above, in one embodiment of the present disclosure, the elastic bending portion 113 is pushed by the object 20 and the counterpart object 10 so as to bend back, reduce a curvature, guide an angle, return to alignment or approach alignment. Thus, the motion body 1 of the present disclosure can better meet actual application requirements (as shown in FIG. 18).

In addition to the embodiments above, in one embodiment of the present disclosure, the elastic bending portion 113 is pushed by the counterpart object 10 so as to bend back, reduce a curvature, guide an angle, return to alignment or approach alignment. Thus, the motion body 1 of the present disclosure can better meet actual application requirements (as shown in FIG. 18).

In addition to the embodiments above, in one embodiment of the present disclosure, the first body 11 can be elastic or can be a metal or plastic substance provided with elasticity after a thermal treatment. Thus, the first body 11 can better meet actual application requirements.

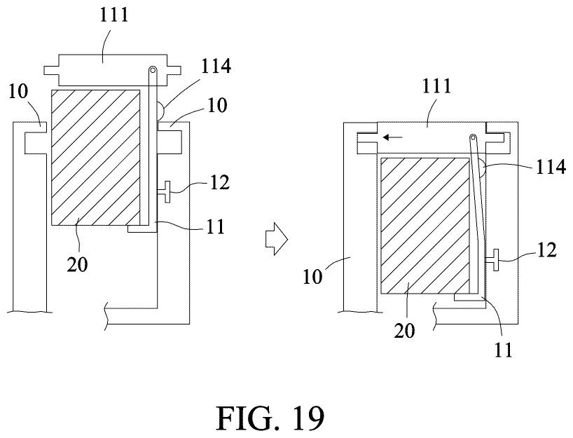

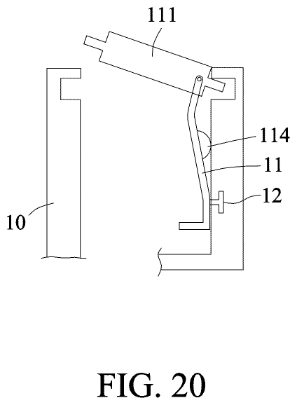

Referring to FIG. 19 to FIG. 20, as shown in the drawings, in addition to the embodiments above, in one embodiment of the present disclosure, the coupling portion 12 is disposed at the first body 11 for the coupling portion 12 to be assembled or fastened with the counterpart object 10, wherein the first body 11 is elastic and has an abutting portion 114 and is for the motion body 1 to be fastened to the object 20. Thus, quick coupling and separation of at least two objects (the counterpart object 10 and the object 20) can be completed to achieve effects of repeatedly quick coupling and separation.

In addition to the embodiments above, in one embodiment of the present disclosure, the abutting portion 114 abuts against the counterpart object 10, and the coupling portion 12 is for coupling the counterpart object 10 for the first body 11 with elasticity to bend and be fastened or assembled with the counterpart object 10. Thus, the first body 11 can coordinate with the abutting portion 114 to better meet actual application requirements.

In addition to the embodiments above, in one embodiment of the present disclosure, the abutting portion 114 abuts against the counterpart object 10, and the coupling portion 12 is for coupling the counterpart object 10 for a handle 111 of the first body 11 with elasticity to bend and be fastened or assembled with the counterpart object 10. Thus, the first body 11 can coordinate with the abutting portion 114 to better meet actual application requirements.

The present disclosure is described by way of the preferred embodiments above. A person skilled in the art should understand that, the embodiments are merely for illustrating the present disclosure and are not to be construed as limitations to the scope of the present disclosure. It should be noted that all equivalent changes, replacements and substitutions made to the embodiments are encompassed within the scope of the present disclosure. Therefore, the legal protection for the present disclosure should be defined by the appended claims.

What is claimed is:

1. A motion body, comprising:
a first body; and
a coupling portion, provided with a second body and an elastic element, the second body disposed at the first body, two ends of the elastic element respectively abutting against the coupling portion and the second body to enable the motion body to be elastically assembled or elastically fastened with a counterpart object.

2. A motion body, comprising:
a first body; and
a coupling portion, disposed at the first body for the coupling portion to be assembled or fastened with a counterpart object, wherein the first body is provided with at least one stop portion for stopping or limiting an object.

3. A motion body, comprising:
a first body; and
a coupling portion, disposed at the first body for the coupling portion to be assembled or fastened with a counterpart object, wherein the first body is provided with an elastic bending portion, the elastic bending portion elastically facing a direction opposite to the coupling portion or elastically facing a direction of the coupling portion, for the motion body to be fastened to an object.

4. A motion body, comprising:
a first body; and
a coupling portion, disposed at the first body for the coupling portion to be assembled or fastened with a counterpart object, wherein the first body is elastic, has an abutting portion and is for the motion body to be fastened to an object.

5. The motion body according to claim 1, wherein the first body is provided with a handle, the handle and the first body are formed integrally, or the handle and the first body are movably assembled, or the handle and the counterpart object are fastened, assembled, labor-saving pushed, pushed or leverage pushed to move the motion body; or, the motion body is provided with a lift portion, which is provided at the first body and is for lifting an object.

6. The motion body according to claim 2, wherein the first body is provided with a handle, the handle and the first body are formed integrally, or the handle and the first body are movably assembled, or the handle and the counterpart object are fastened, assembled, labor-saving pushed, pushed or leverage pushed to move the motion body; or, the motion body is provided with a lift portion, which is provided at the first body and is for lifting an object.

7. The motion body according to claim 3, wherein the first body is provided with a handle, the handle and the first body are formed integrally, or the handle and the first body are movably assembled, or the handle and the counterpart object are fastened, assembled, labor-saving pushed, pushed or leverage pushed to move the motion body; or, the motion body is provided with a lift portion, which is provided at the first body and is for lifting an object.

8. The motion body according to claim 4, wherein the first body is provided with a handle, the handle and the first body are formed integrally, or the handle and the first body are movably assembled, or the handle and the counterpart object are fastened, assembled, labor-saving pushed, pushed or leverage pushed to move the motion body; or, the motion body is provided with a lift portion, which is provided at the first body and is for lifting an object.

9. The motion body according to claim 1, wherein the counterpart object is provided with a movement space, and the coupling portion moves in the movement space; or the movement space is provided with an entrance and a passage, and the coupling portion enters the entrance and moves in the passage; or the movement space is provided with at least one block portion, and the block portion blocks the coupling portion at a residing position, a pause position or a restricted region; or the block portion is provided with an entrance on a top or at a bottom, or two block portions are provided with an entrance on a top, in a middle or at a bottom, respectively, and the entrance is for the coupling portion to enter; or the coupling portion blocks, passes through, fittingly engages with or elastically presses against the block portion by elastic expansion/retraction of the elastic element; or the motion body or an object resides, pauses or restricts a region at the coupling portion or a blocking position of at least one block portion along with the first body.

10. The motion body according to claim 2, wherein the counterpart object is provided with a movement space, and the coupling portion moves in the movement space; or the movement space is provided with an entrance and a passage, and the coupling portion enters the entrance and moves in the passage; or the movement space is provided with at least one block portion, and the block portion blocks the coupling portion at a residing position, a pause position or a restricted region; or the block portion is provided with an entrance on a top or at a bottom, or two block portions are provided with an entrance on a top, in a middle or at a bottom, respectively, and the entrance is for the coupling portion to enter; or the coupling portion blocks, passes through, fittingly engages with or elastically presses against the block portion by elastic expansion/retraction of the elastic element; or the motion body or an object resides, pauses or restricts a region at the coupling portion or a blocking position of at least one block portion along with the first body.

11. The motion body according to claim 3, wherein the counterpart object is provided with a movement space, and the coupling portion moves in the movement space; or the movement space is provided with an entrance and a passage, and the coupling portion enters the entrance and moves in the passage; or the movement space is provided with at least one block portion, and the block portion blocks the coupling portion at a residing position, a pause position or a restricted region; or the block portion is provided with an entrance on a top or at a bottom, or two block portions are provided with an entrance on a top, in a middle or at a bottom, respectively, and the entrance is for the coupling portion to enter; or the coupling portion blocks, passes through, fittingly engages with or elastically presses against the block portion by elastic expansion/retraction of the elastic element; or the motion body or an object resides, pauses or restricts a region at the coupling portion or a blocking position of at least one block portion along with the first body.

12. The motion body according to claim 4, wherein the counterpart object is provided with a movement space, and the coupling portion moves in the movement space; or the movement space is provided with an entrance and a passage, and the coupling portion enters the entrance and moves in the passage; or the movement space is provided with at least one block portion, and the block portion blocks the coupling portion at a residing position, a pause position or a restricted region; or the block portion is provided with an entrance on a top or at a bottom, or two block portions are provided with an entrance on a top, in a middle or at a bottom, respectively, and the entrance is for the coupling portion to enter; or the coupling portion blocks, passes through, fittingly engages with or elastically presses against the block portion by elastic expansion/retraction of the elastic element; or the motion body or an object resides, pauses or restricts a region at the coupling portion or a blocking position of at least one block portion along with the first body.

13. The motion body according to claim 1, wherein the coupling portion is provided with a restricting portion, and the coupling portion enters the entrance, and is elastically fastened, elastically pressed, limited or temporarily limited at the limiting portion by the restricting portion; or the limiting portion is two in quantity, and the coupling portion is elastically fastened, elastically pressed, limited or temporarily limited at each of the limiting portions in a two-stage or multi-stage manner.

14. The motion body according to claim 2, wherein the coupling portion is provided with a restricting portion, and the coupling portion enters the entrance, and is elastically fastened, elastically pressed, limited or temporarily limited at the limiting portion by the restricting portion; or the limiting portion is two in quantity, and the coupling portion is elastically fastened, elastically pressed, limited or temporarily limited at each of the limiting portions in a two-stage or multi-stage manner.

15. The motion body according to claim 3, wherein the coupling portion is provided with a restricting portion, and the coupling portion enters the entrance, and is elastically fastened, elastically pressed, limited or temporarily limited at the limiting portion by the restricting portion; or the limiting portion is two in quantity, and the coupling portion is elastically fastened, elastically pressed, limited or temporarily limited at each of the limiting portions in a two-stage or multi-stage manner.

16. The motion body according to claim 4, wherein the coupling portion is provided with a restricting portion, and the coupling portion enters the entrance, and is elastically fastened, elastically pressed, limited or temporarily limited at the limiting portion by the restricting portion; or the limiting portion is two in quantity, and the coupling portion is elastically fastened, elastically pressed, limited or temporarily limited at each of the limiting portions in a two-stage or multi-stage manner.

17. The motion body according to claim 1, wherein the first body is provided with at least one stop portion which is for stopping or limiting an object; or the stop portion is provided with a rail, and the object moves along a direction of the rail; or the first body is provided with at least one fixing portion, and an object is fixed at the first body by the fixing portion; or the first body is elastic or a metal or plastic substance provided with elasticity after a thermal treatment.

18. The motion body according to claim 2, wherein the first body is provided with at least one stop portion which is for stopping or limiting an object; or the stop portion is provided with a rail, and the object moves along a direction of the rail; or the first body is provided with at least one fixing portion, and an object is fixed at the first body by the fixing portion; or the first body is elastic or a metal or plastic substance provided with elasticity after a thermal treatment.

19. The motion body according to claim 3, wherein the first body is provided with at least one stop portion which is for stopping or limiting an object; or the stop portion is provided with a rail, and the object moves along a direction of the rail; or the first body is provided with at least one fixing portion, and an object is fixed at the first body by the fixing portion; or the first body is elastic or a metal or plastic substance provided with elasticity after a thermal treatment.

20. The motion body according to claim 4, wherein the first body is provided with at least one stop portion which is for stopping or limiting an object; or the stop portion is provided with a rail, and the object moves along a direction of the rail; or the first body is provided with at least one fixing portion, and an object is fixed at the first body by the fixing portion; or the first body is elastic or a metal or plastic substance provided with elasticity after a thermal treatment.

21. The motion body according to claim 4, wherein the abutting portion abuts against the counterpart object, and the coupling portion is for coupling the counterpart object, for the first body with elasticity to bend and be fastened or assembled with the counterpart object; or wherein the abutting portion abuts against the counterpart object, the coupling portion is for coupling the counterpart object, for a handle of the first body with elasticity to bend and be fastened or assembled with the counterpart object.

22. The motion body according to claim 1, wherein the object is provided with a connector, the counterpart object is provided with a corresponding connector, and the motion body is for docking, plugging or hot-plugging with the corresponding connector by the connector; or the object is provided with at least one positioning portion which is positioned or limited with the motion body.

23. The motion body according to claim 2, wherein the object is provided with a connector, the counterpart object is provided with a corresponding connector, and the motion body is for docking, plugging or hot-plugging with the corresponding connector by the connector; or the object is provided with at least one positioning portion which is positioned or limited with the motion body.

24. The motion body according to claim 3, wherein the object is provided with a connector, the counterpart object is provided with a corresponding connector, and the motion body is for docking, plugging or hot-plugging with the corresponding connector by the connector; or the object is provided with at least one positioning portion which is positioned or limited with the motion body.

25. The motion body according to claim 4, wherein the object is provided with a connector, the counterpart object is provided with a corresponding connector, and the motion body is for docking, plugging or hot-plugging with the corresponding connector by the connector; or the object is provided with at least one positioning portion which is positioned or limited with the motion body.
